(19) United States
(12) Patent Application Publication
(10) Pub. No.: US 2006/0086994 A1
(43) Pub. Date: Apr. 27, 2006

(54) Nanoelectromechanical components

(76) Inventors: Susanne Viefers, Oslo (NO); Tomas Nord, Amsterdam (NL); Jari Kinaret, Molndal (SE); Magnus Jonsson, Vastra Frolunda (SE); Sven Axelsson, Finspang (SE)

Correspondence Address: HARNESS, DICKEY & PIERCE, P.L.C., P.O. BOX 8910, RESTON, VA, 20195, US

(21) Appl. No.: 11/128,437

(22) Filed: May 13, 2005

Related U.S. Application Data
(60) Provisional application No. 60/570,882, filed on May 14, 2004.

(51) Int. Cl. H01L 29/84; H01L 31/109

(52) U.S. Cl. 257/415; 257/419; 257/14

(57) ABSTRACT

A nanotube device is disclosed which includes a nanotube with a longitudinal and a lateral extension, a structure for supporting at least a first part of the nanotube, and a first device for exerting a force upon the nanotube in a first direction defined by its lateral extension. At least a second part of the nanotube protrudes beyond the support of said structure, so that when said force exceeds a certain level, the second part of the nanotube will flex in the direction of its lateral extension, and thereby close a first electrical circuit. Suitably, the first device for exerting said force upon the nanotube is an electrical means, the force being created by applying a voltage to the means. The device allows for quantum mechanics tunnel effects, both at a source and at a drain electrode.

### FIELD OF THE INVENTION

The present invention relates to a nanotechnology component and more particular to a nanoelectromechanical component having means for influencing the flow of a small electrical current through the component.

### TECHNICAL BACKGROUND

Nanotechnology is an expanding research field in which development of nanoelectromechanical systems (NEMS) is included. NEMS is based on an electromechanical coupling in systems with length scales in the nanometer range. The small length scale of these systems allows for high intrinsic mechanical frequencies, and electromechanical resonances in the GHz-regime are possible. These resonances can be used to design high frequency electronic components on the nanometer scale.

The present invention is a further development of the system presented in patent application PCT/SE02/00853: A Nanomechanical Relay Device and having three of the inventors in common, and on components incorporating either the original or the modified, and operating design at high frequencies. Prior art also includes DE 10034315 A1 and WO 0161753 A1 to Infineon Technologies AG.

### SUMMARY OF THE INVENTION

The present invention is a nanoelectromechanical device. The device comprises a nanotube, preferably a conducting nanotube, suitably a carbon nanotube.

The device further includes a non-conducting supporting structure, made of a non-conducting material such as for example silicon, Si, which supports at least a first portion of the nanotube, with another second portion of the nanotube protruding beyond the supporting structure, and thus being unsupported. The first, supported, portion of the nanotube is connected to an electrode, referred to from row on as the source electrode, by means of a source-tube connection having special properties.

The source-tube connection is a connection where a source-to-tube distance between the conducting source electrode and the conducting nanotube is in the range where quantum mechanics phenomena, in particular the so called tunnel effect, also called quantum leakage can occur.

The device according to the invention also provides means for controlling the magnitude of said tunnel effect. Said means preferably comprise one or more gate electrodes, see below.

Providing such a tunnelling contact at the source-tube junction has the advantages of:

enabling the control of exact number of electrons in the nanotube;

a system that can be so devised that every new added amount of charge, which is tunnelled into the nanotube, will correspond to a specific mechanical equilibrium position of the nanotube before the potential is levelled out. This results in a precise mechanism of transportation, usable as a kind of “stepper motor”.

The supporting structure is suitably shaped as a terrace, and thus has a “step-like” structure, with an upper level, and a lower level, where the two levels are interconnected by a wall-like shape of the supporting structure. The difference in height between the two levels of the structure as defined by the height of the wall is referred to by the letter h. It should be noted that the use of the word “level” throughout this description refers to a difference in dimensions which gives the structure a preferably step-like form either in the horizontal or in the vertical orientation of the device.

On the lower level of the structure, there are arranged two or more additional electrodes, some of which being referred to as gate electrodes and others as the drain electrodes. The gate electrode is located at a distance L_{G} to the nearest point of the wall, and the corresponding distance for the drain electrode is denoted as L_{D}, where L_{G} suitably is smaller than L_{D}.

The total extension of the protruding part of the nanotube is preferably within the interval of 50 to 150 nm, suitably of the order of approximately 100 nm, with the height h being approximately in the order of size of 3 nm.

When a voltage is applied to the gate electrode, a resulting capacitive force will act on the nanotube, in the direction towards the gate electrode, which is thus a direction defined by the lateral extension of the nanotube. When the mentioned force acts, the nanotube will deflect towards the gate electrode, thereby reducing a tube-to-drain distance between the nanotube and a drain electrode. The amount of deflection is such that the distance between the tube tip and the drain electrode can be varied from a distance with very high impedance, over a distance where tunnelling phenomena is dominant, to a distance of zero, where the tube tip directly a [symbol] uts the drain electrode, and impedance is very low.

By applying voltages of different amplitudes and frequencies the device can be controlled to give different characteristica for a source-drain current flowing from the source electrode through the tube to the drain electrode, as will be explained below.

### BRIEF DESCRIPTION OF THE DRAWINGS

The invention will be described in detail below with reference to the accompanying drawings, in which:

FIG. 1 shows a schematic side view of a nanoelectromechanical component according to a preferred embodiment of the present invention.

FIG. 2 shows an equivalent circuit diagram of the component in FIG. 1.

FIG. 3a-f shows schematically components having different configurations with several gate and drain electrodes.

FIG. 4a shows a stability diagram showing the positions of zero net forces on the tube of the component in FIG. 1 for different gate voltages.

FIG. 4b shows the current as a function of gate voltage corresponding to the stability plot in FIG. 4a.

FIG. 5a shows a stability diagram for a non-contact mode system.

FIG. 5b shows a diagram of the current as a function of source-gate voltage, corresponding to the stability plot in FIG. 5a.

FIG. 6 shows a diagram of resonance frequency for a non-contact mode system as a function of gate voltage.

FIG. 7 shows a diagram of the vibration peak to peak amplitude for a contact mode system as a function of modulation frequency.

FIG. 8a shows a diagram of maximum and minimum displacements of the tube in a contact mode system as a function of modulation frequency.

FIG. 8b shows a diagram similar to that in FIG. 8a, when the tube switches s [symbol] ate to a position close to the surface for some frequencies.

FIG. 9 shows a diagram of observed resonances for a non-contact mode system as a function of modulation frequency and gate voltage bias.

FIG. 10a-b show diagrams of frequency responses in non-contact mode at operation.

FIG. 11 shows a component according to the invention as a box.

FIG. 12 shows a schematic illustration of a filter circuit embodiment of the invention.

FIG. 13 shows a schematic illustration of a detector application of an embodiment of the invention.

FIG. 14 shows a schematic illustration of a voltage controlled oscillator according to an embodiment of the invention.

FIG. 15 shows a schematic illustration of a variable capacitor circuit according to an embodiment of the invention.

FIG. 16 shows a nanoelectromechanical component provided with a cavity enabling greater oscillations of the nanotube.

### DETAILED DESCRIPTION OF PREFERRED EMBODIMENTS

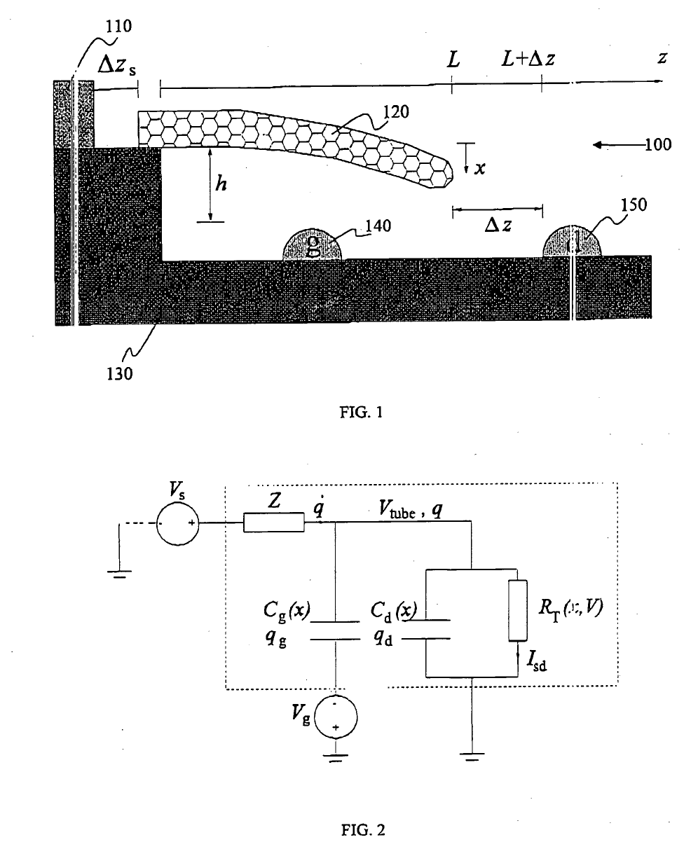

An illustration of the basic system is depicted in FIG. 1 and the corresponding equivalent circuit is shown in FIG. 2. A nanotube or a nanowhisker 120, preferably a conducting nanotube, suitably a carbon nanotube, of length L is placed on a terraced non-conducting substrate 130 such that a tip end 160 is free to move and a base end 1 [symbol] 0 is firmly connected to the terraced non-conducting substrate 130 on the higher part of the terrace—the term higher refers to the figure and does imply a particular spatial orientation. The tube-source contact may be a tunnel junction, corresponding to: Δzₛ>0, or a contact allowing continuous charge transfer if Δzₛ=0. The impedance of the tube-source contact is denoted by Z and the electrostatic potentials on the source, gate and drain electrodes are denoted Vₛ, V_{g}, V_{d}, respectively. The potential o [symbol] the tube is V. The direction along the tube axis is denoted z and the tube tip 160 is located at z=L. Two additional electrodes (gate and drain) are positioned beneath the free end of the tube at z_{g}<L and z_{d}=L+Δz respectively. The ratio z_{g}/L=zᵣ gives the relative position of the gate compared to the tube tip, and Δz≧0 distinguishes between two modes of operation. The “contact mode” is defined by Δz=0 whereas the “non-contact mode” occurs for Δz>>λ, where λ≈0.5 Å is the tunnelling length.

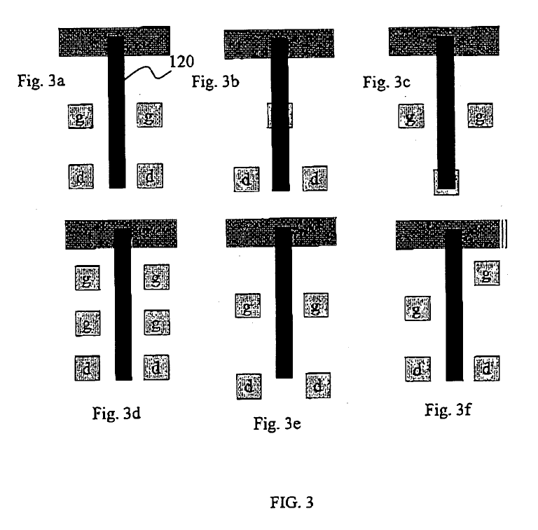

FIG. 3 shows from above how the structure may also comprise a multitude of gate and drain electrodes.

FIG. 3a shows an arrangement with two gate electrodes g and two drain electrodes d. The gate electrodes are arranged, one on each side of the nanotube 120 and below.

The drain electrodes d are arranged also one on each side and below of the nanotube 120, and closer to the tip of the tube than the gate electrodes g. This electrode placing enables a greater freedom in control of vibration modes of the nanotube 120.

FIG. 3b shows an arrangement with one gate electrode g and two drain electrodes d. The gate electrode g is arranged directly under the nanotube 120, whilst the two drain electrodes d are arranged, one on each side of the nanotube opposite of each other.

FIG. 3c shows an arrangement with two gate electrodes g and one drain electrode d. The gate electrodes are arranged, one on each side of the nanotube 120 and opposite of each other.

FIG. 3d shows an arrangement with four gate electrodes g, and two drain electrodes d. The gate electrodes g are arranged two on each side of the nanotube 120 in a quadratic or rectangular fashion in pairs. The drain electrodes d are arranged one on each side of the nano-tube opposite of each other.

FIG. 3e shows an arrangement with two gate electrodes g and two drain electrodes d, where the gate electrodes g are arranged as in FIG. 3a and where the drain electrodes d are arranged beyond the nanotube 120, one on each side of the imaginary extension of said tube 120.

FIG. 3f shows an arrangement with two gate electrodes g and two drain electrodes d where the gate electrodes are arranged asymmetrically with reference to the nanotube 120.

The arrangement of FIG. 3a-3f allows for greater and different freedom in control of vibration modes of the nanotube. These arrangements make it possible to superimpose movements orthogonally to the elongation of the tube 120 different from the deflection mentioned in connection with FIG. 1.

The tube tip can be electrostatically bent towards the drain electrode by controlling the voltages on the electrodes, thereby inducing an excess charge q on the tube. The deflection of the tube tip is measured vertically towards the substrate and is denoted x. In the contact mode, the tube mechanically contacts the drain electrode when x=h, where h is the vertical distance from the straight tube to the contact. In the non-contact mode, the tube never reaches the electrode. The tube tip-drain contact is a tunnel junction, and decreasing the distance between the tube and the drain electrode reduces the tunnelling resistance R_{T}(x,V) and allows a tunnelling current I_{sd} to flow over the junction. The basic principle of operation is thus to mechanically reduce the barrier width by means of a capacitive coupling, which in turn leads to an electric current in the system.

In other words, FIG. 1 shows how an end of a conducting nanotube or nanowhisker of length L is free hanging over a terraced non-conducting substrate on which additional electrodes (gate and drain) are placed underneath the tube. The other end of the tube is electrically connected to a source electrode, the distance Δzₛ controls the tunnelling resistance of the source junction. An ohmic contact is possible if Δzₛ=0. The vertical distance between a straight tube and the gate and drain electrodes is h and the horizontal distance between the tube tip and the electrode is Δz. The tube tip can be deflected a distance x in the vertical direction by means of the voltages on the electrodes. A large enough deflection reduces the tunnelling resistance enough to allow for a tunnelling current from the tube tip to the drain electrode. FIG. 2 shows the corresponding equivalent circuit of the system. The parts within the dashed line are the equivalent circuit of the component of FIG. 1, whereas the parts outside said dashed line are external parts. This “box notation” will be used later. The tube-source junction is has impedance Z over which a charge q flows, the tube-gate coupling is purely capacitive with capacitance C_{g}(x) and the tube is connected to the drain by a tunnel junction with tunnelling resistance R_{T}(x,V) and capacitance C_{g}(x). A stochastic tunnelling current I_{sd}(x,V) flows between the tube and the drain electrode

General Considerations

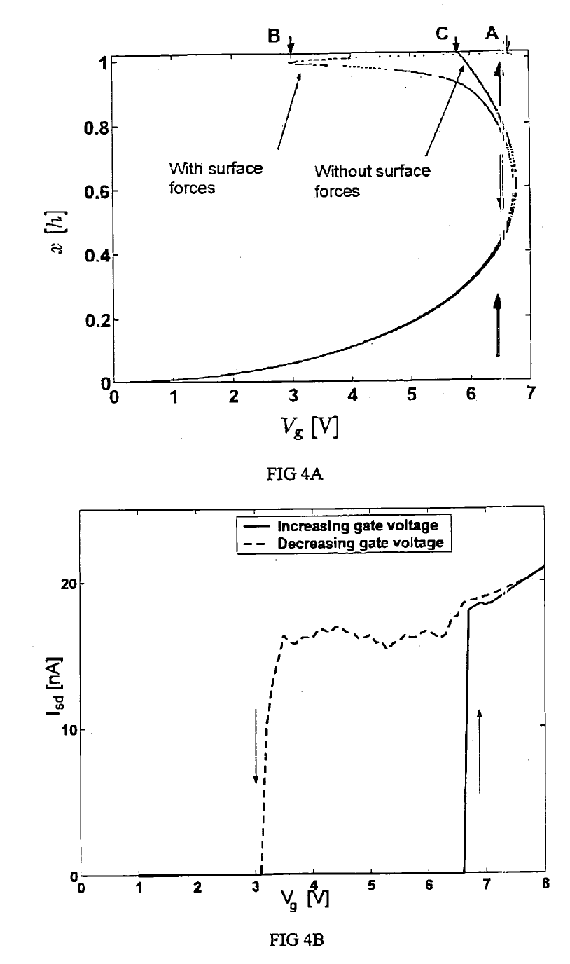

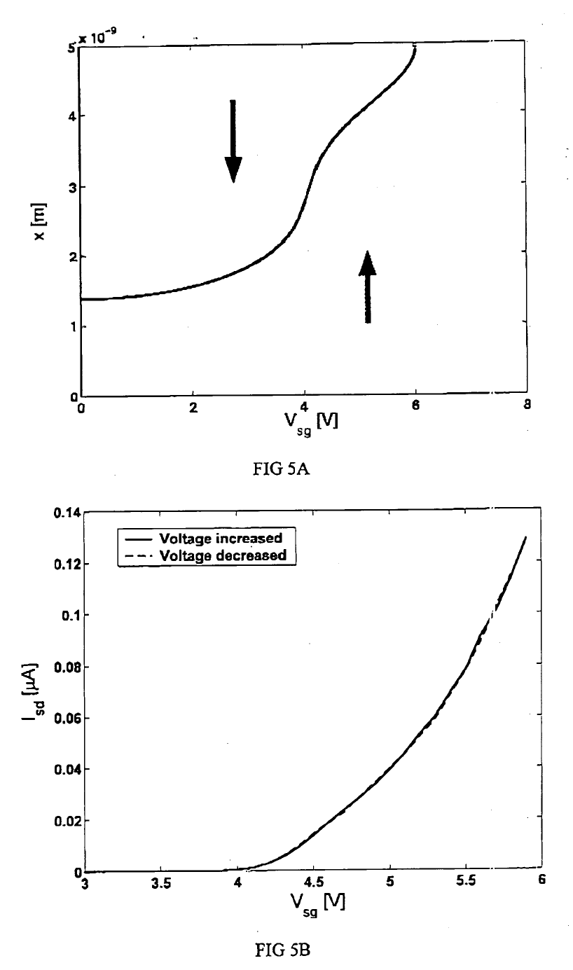

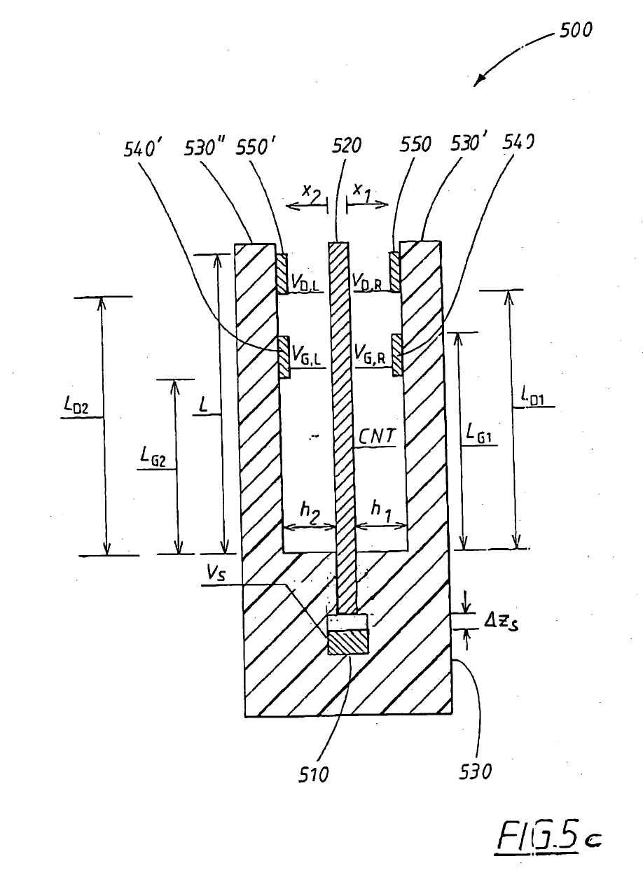

There is a strong coupling between the electrical and mechanical degrees of freedom in the system. The geometry of the system depends on the electrostatic potentials on the electrodes, and the electrical properties depend in turn of the geometry of the system. For a typical contact mode system, the equilibrium tube position as a function of gate voltage can be deduced from FIG. 4a and the corresponding current voltage characteristics is depicted in FIG. 4b. For the non-contact mode system the corresponding plots are depicted in FIGS. 5aand 5b.

Multiple Nanotubes

In one embodiment several nanorelays are arranged parallelly to each other to increase the possible current through such a structure.

Materials and Structures

In alternative embodiments the tube 120 is a carbon nanotube, a silicon c [symbol] bide nanotube, a nanowire or a nanowhisker.

FIG. 4a shows a stability diagram with and without short range surface forces for a typical contact mode system. The curve shows the positions of zero net force on the tube (or local equilibria) as functions of gate voltage (at constant Vₛ₌0.01 V) and deflection x (in units of h). The large arrows show the direction of the force on each side of the curves, indicating one local equilibrium to be unstable in the region where three equilibria exist. The required voltage for pulling the tube to the surface (pull-in voltage) is given by A(≈6.73V). This voltage is not significantly affected by surface forces. A tube at the surface will not leave the surface until the voltage is lower than the release voltage, B and C in the figure. Note that A>B, C, which indicates a hysteretic behaviour in the IV_{g-}characteristics, a feature significantly enhanced by surface forces. FIG. 4b shows the current voltage characteristics corresponding to the stability plot in FIG. 4a with surface forces.

FIG. 5a shows a stability diagram for the non-contact mode system. The arrows show the direction of the force on the tube tip in the two regions. Only one equilibrium position for each voltage is seen for this set of design parameters, and the system characteristics have no hysteresis. FIG. 5b shows source-drain current versus source-gate voltage characteristics corresponding to the stability plot in FIG. 5a.

FIG. 5c shows a top view of another embodiment 500 of the invention. This embodiment 500 comprises a nanotube device similar to that shown in FIG. 1 and described above, but with the supporting, terraced structure 530 additionally comprising a structure 530″ on a third level, said third level 530″ being located essentially in parallel with the second level 530′, but on a an opposite side of the protruding part of the nanotube 520.

The embodiment 500 also comprises tunnelling source-tube junction due to the distance Δzₛ between a source 510 and a nanotube 520.

The embodiment 500 comprises essentially all of the features of the device in FIG. 1, and additionally comprises second means 540′ for exerting a force upon the nanotube 520 in a second direction defined by its lateral extension, so that when said force exceeds a certain level, the second part of the nanotube will flex in the second direction of its lateral extension, and thereby close or making a tunnel junction in a second electrical circuit. Said second direction is, as will be realized from FIG. 5, the direction which is towards the means 540′, which are preferably a second gate electrode, the second, protruding part of the nanotube 520 will flex in the second direction of its lateral extension, and thereby close a second electrical circuit. This second electrical circuit is suitably defined by the source electrode 510 described in connection with FIG. 1, and a second drain electrode 550′ located on the third level 530″ of the supporting structure 530.

The second gate and drain electrodes are located at distances L_{G2} and L_{D2}, respectively, from the wall of the terraced structure.

Short Range Forces

Short range surface forces (forces with a stronger distance dependence than the Coulomb interaction) influence the operational characteristics if the tube at any time gets closer than a few nanometers from mechanical contact with any part of the structure not including the source electrode. The primary net effect of these forces is to increase hysteresis. This makes a memory element a particularly interesting application particularly for the contact mode structure. Such a memory element can be designed to be either volatile or non-volatile using, for example, the three-terminal contact mode system or the five terminal structure of patent application PCT/SE02/00853: A Mechanical Relay Device. In this respect “volatile” refers to an embodiment, where the nanotube is designed to have a mechanical stiffness, such that the mechanical forces due to said stiffness are enough to loosen the nanotube from the drain electrode when V_{g} becomes close to zero. The stiffness can be achieved by e.g. a short nanotube or a nanotube with large diameter. “Non-volatile” refers to an embodiment, where it is necessary to provide a current pulse, heating the electrode to loosen said nanotube from the drain electrode. Such a current pulse can be provided by a pulse-generating device connected to the source.

High Frequency Properties

The high intrinsic mechanical frequency of the device can be used to design components based on a nanoelectromechanical resonances with resonance frequencies reaching the GHz regime.

Electromechanical Resonances

Contact Mode

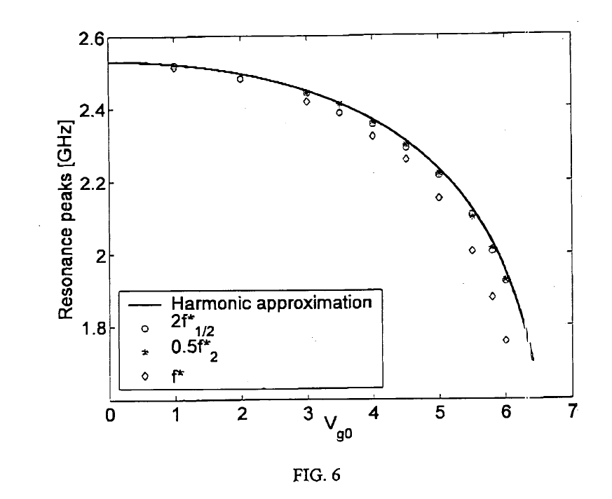

The equilibrium positions of the tube, which can be deduced from FIGS. 4a and 5a, are determined by the local minima of the total tube potential The mechanical resonance frequency is determined by the curvature of the total potential near the potential minima (harmonic approximation). Since the total potential can be controlled by the external voltages, both the tube equilibrium position and the mechanical resonance frequency are controllable by electrostatic means. Hence, the resonance frequency is a function of gate voltage as plotted in FIG. 6 for a contact mode device. The lowest mechanical resonance frequency, denoted by ƒ*,can be varied over several GHz by tuning the gate voltage bias. Non-linear effects are important when considering the resonances. These non-linear effects change the location of the main resonance peak and make resonances at half and twice the resonance frequency possible. These resonances are denoted by ƒ*_{1/2} and ƒ*₂ respectively.

In other words, FIG. 6 shows the lowest resonance frequency of a typical contact mode system as a function of gate voltage. The values are compared to a prediction based on a harmonic approximation to the potential profile.

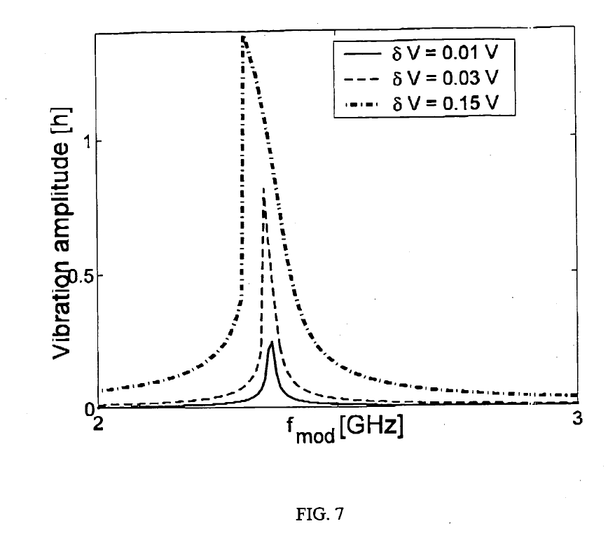

FIG. 7 shows the vibration amplitude (peak to peak) for the contact mode system as a function of modulation frequency for different values of the modulation amplitude δV. If the amplitude is small, the line shape is symmetric, whereas for larger amplitudes the shape is asymmetric and the peak position is shifted.

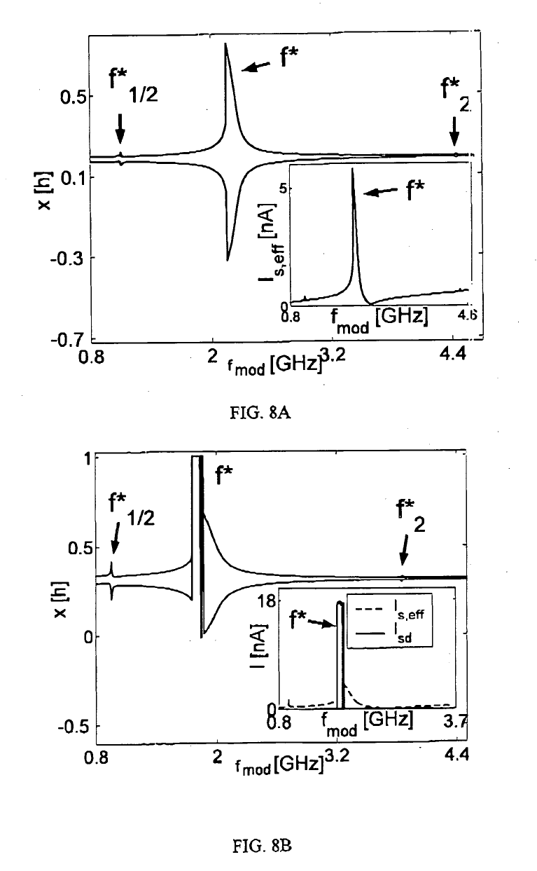

When a high frequency modulation is applied to the gate electrode of a contact mode structure, it may result in two qualitatively different outcomes. In the first case, the system's trajectory in phase space approaches a limit cycle, in which the tube never mechanically contacts the surface, but oscillates with a substantial amplitude. Due to the very high tunnelling resistance for large tube-drain separations, tunnel current through the system is negligible. However, since the geometry of the structure changes in time, so do the geometric capacitances, and also the charge on the tube changes in time with the same frequency. This results in a AC displacement current at the source and drain contacts with a frequency corresponding to the mechanical oscillation frequency. The frequency response of the system in this case is shown in FIG. 8a and the effective value of the displacement current i_{s,eff}, determined assuming sinusoidal charge transfer as i_{s,eff}=max(∂_{I}/\sqrt{2}), is depicted in the inset. As can be seen, the resonance is accompanied by a large change in the displacement current. In the second case, if the oscillation amplitude is large enough, the system may impinge on the drain contact for a range of frequencies. Interactions between the tube and the drain electrode cause the tube lose some of its energy and help the tube to get trapped to a stationary state near the surface. The potential minimum near the surface corresponds to a high frequency compared to the minima far from the surface, implying that the gate modulation frequency is no longer at resonance, and energy transfer to a tube at the contact position is inefficient. The device has changed its state as a result of the modulation and a tunnelling current is feasible. The tube will continue to reside at the surface even after the gate modulation is removed. Thus, the system has a built-in memory, which remembers if a modulation within a certain frequency range has been applied. The frequency scan in this case is shown in FIG. 8b, where, for a narrow interval near a resonance frequency, the tube ends up near the contact. Only in this narrow region do we get a non-zero tunnelling current. In both cases there are clearly visible resonances at half and the double frequency and, also, the line shape of the main resonance is asymmetric. Both these characteristics are due to deviations from the quadratic potential shape.

In other words, FIG. 8 shows the maximum and minimum displacements in a contact mode structure in steady state for gate voltage biases (a) V_{g0}=5 V and (b) V_{g0}=6 V with gate voltage modulation δV=0.1 V with frequency ƒ_{mod}. The largest peak corresponds to the resonance frequency, and the smaller to half and double frequency peaks. Inset in FIG. 8a shows the amplitude of the source junction displacement current as a function of frequency. In FIG. 8b is shown how the tube switches state to a position close to the surface for some frequencies allowing a non-zero tunnelling current from the tube to the drain, i.e. “switches state” implies that the tube hits the substrate and sticks for certain frequencies because the amplitude of the oscillation is frequency dependent. Inset in FIG. 8b depicts both effective displacement current I_{s,eff}, and the drain tunnelling current [symbol] _{sd}.

Non-Contact Mode

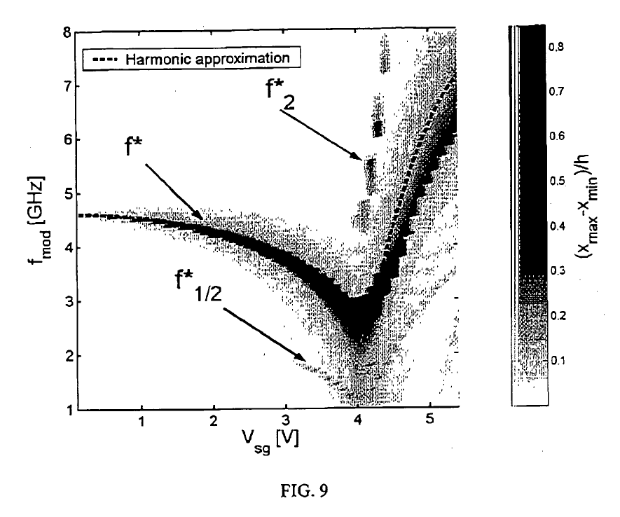

As for the contact mode we can predict resonance frequencies for a specific gate voltage using a harmonic approximation to the potential. This prediction is the dashed line in FIG. 9. The prediction is compared to the observed oscillation amplitudes as a function of both gate voltage and modulation frequency. The dark areas correspond to resonances. The observed resonances follow approximately the qualitative behaviour of the harmonic approximation, and the frequency for the main resonance can be changed even more than was possible in the non-contact mode system. Also note the ƒ*_{1/2} and ƒ*₂ branches that are visible even in this case.

In other words, FIG. 9 shows observed resonances in the non-contact mode of operation of the system as a function of modulation frequency and gate voltage bias. The harmonic approximation (dashed line) agrees well with the observed resonances in the low bias region and deviates from the predicted value for larger voltages. Note the clearly visible ƒ*_{1/2} and ƒ*₂-branches.

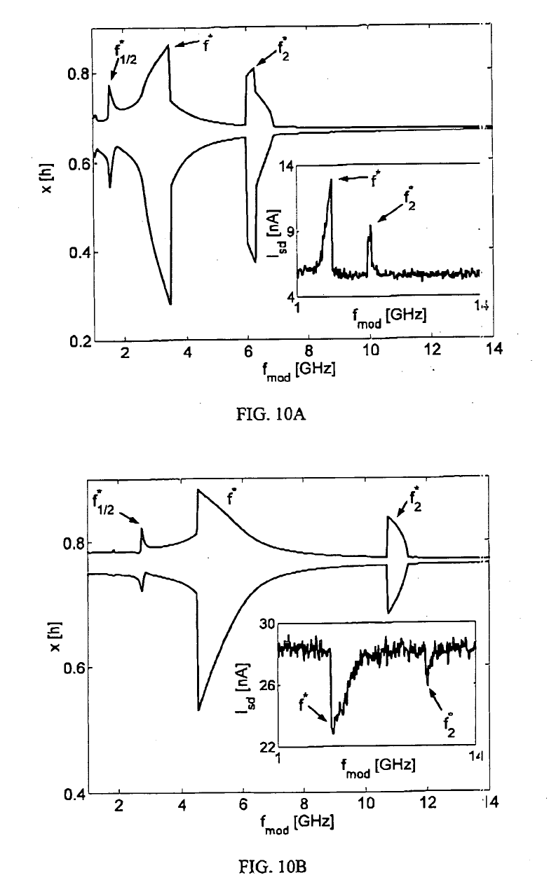

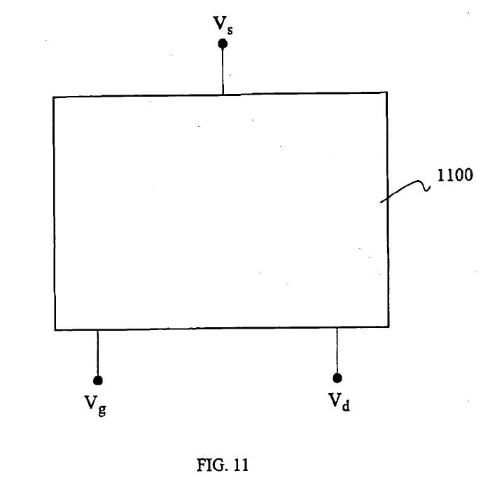

The current through the system in the non-contact mode is significantly different from the current in the contact mode system. The large source-drain voltage allows for a current without mechanical contact and a non-zero tunnelling current is expected for all frequencies. The current changes at resonance due to the tube oscillations, and may either increase or decrease depending on bias voltages—if the non-oscillatory position resulted in a large current, oscillations tend to reduce it and vice versa. These two different cases are depicted in FIG. 10, which shows the minimum and maximum tube deflection in the limit cycle, and the insets show the corresponding tunnelling currents. The most important conclusion from these figures is that the resonance changes the current, which implies that the resonance is detectable electrically. The line shape of the resonances is highly asymmetric, implying that the current changes abruptly on one side of the resonant frequency.

In other words, FIG. 10 shows the frequency response in the non-contact mode of operation. Biasing points are (a) V_{g0}=4.3 V and (b) V_{g0}=4.8 V, amplitude of AC modulation is δV=0.1 V. The main resonance peak is highly asymmetric and both double-frequency and a half-frequency peaks are visible. Insets show the average tunnelling current as a function of frequency. The average current increases at the resonance in FIG. 10a and decreases in FIG. 10b. The sign and magnitude of the current change depend on the shape of the potential.

Dimensions

Dimensions vary with application and expectation of dynamics. In theory typical lengths are 80-100 nanometer, the terrace height h typically 8 nanometer, and the diameter typically 8 nanometer.

Examples of Applications

Below are examples of components that can be designed using the system described earlier.

Box Notation

For simplicity, the examples are described using a box notation. The box contains a nanomechanical relay device, either in the contact or non-contact mode, and is connected to an external circuit through source, gate, and drain contacts, see FIG. 11. Thus, we consider the system as a box which is connected to external circuits through three or five electrodes. If the relay utilizes the other configuration, e.g. the five-terminal configuration discussed in the former patent application PCT/SE02/00853) there are several gate and drain contacts.

Memory Element

A memory element application is a potential application for the relay. Due to i [symbol] elastic collisions between the tube and drain electrode in the contact mode system vary fast writing times are attainable. The memory cell may be both volatile, requiring external voltage sources to store its value, or non-volatile, capable of maintaining its state even in the absence of external voltages. In the memory application, the box should contain a relay in the contact mode, with sufficient hysteresis as depicted in FIG. 4b. The conducting state, in which the tube end is in close proximity to the drain electrode, is a logical “1”, while the non-conducting state is a logical “0”. The memory cell is volatile, if the lower edge of the hysteresis loop, denoted by B in FIG. 4b, is positive. If the hysteresis loop extends to zero gate voltage, the memory element maintains its state even without external voltages, and is non-volatile. A non-volatile memory element can be reset to a non-conducting state by applying a large voltage pulse V_{sd}, thereby heating up the tube-drain contact. The resulting vigorous electron movements will discharge the tube from the drain electrode.

Filter

Exploiting the electromechanical resonance the system can be used as a filter by applying the input AS signal to the gate and reading of the output signal at the drain. Modulating the gate voltage with a signal with several frequency components suppresses frequency components with frequencies out of resonance. Since the resonance frequency is tuneable using the gate voltage bias V_{g0}, the system acts as a tuneable filter. The nanoelectromechanical element in this case can be either in the contact or non-contact mode, and the frequency range of the filter can be read off FIGS. 6 and 9.

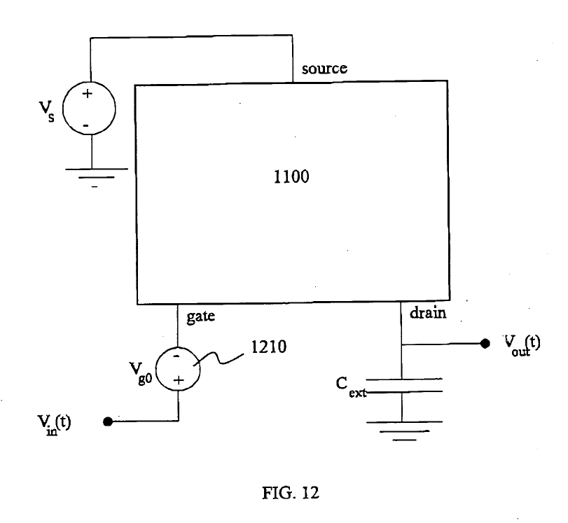

FIG. 12 shows schematically a filter application of the relay. The internal capacitances are functions of time which yields an output voltage which also varies in time with the frequency with which the tube oscillates. A gate voltage modulator 1210 is connected between the voltage input Vᵢₙ and the gate, to add an AC voltage.

Variable Bandwidth Detector

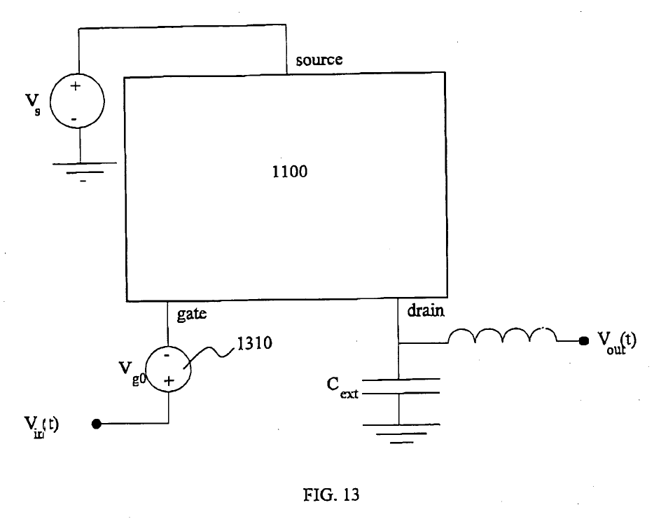

The system can be used as detector (FIG. 13) which detects signals that are sufficiently close to the resonance frequency. The gate of the device 1600 is connected to a gate voltage modulator 1310. A gate voltage modulation with an appropriate frequency induces a response. The specific features of the response depend on the mode of operation. For the contact mode system, the tube changes its logical state which results in a change in the tunneling resistance, and consequently a DC current at the drain, as shown in FIG. 8b. When the gate modulation is turned off, the tube remains at the surface (unless the gate bias is removed, or even in the absence of gate bias if the design parameters correspond to those of a non-volatile memory element) and the detector has a memory. The bandwidth of the detector is a function of both gate bias and signal amplitude and can be tuned. The resonance frequency is, as mentioned earlier, a function of gate bias. Thus, both the detector bandwidth and response frequency can be tuned. If the nanoelectromechanical component is in the non-contact mode, the current response at drain may have either sign (cf. FIG. 10), and the detector has no built-in memory.

FIG. 13 shows schematically a detector application. If a signal with an appropriate frequency is applied to the gate, the system changes its logical state which results in a source (drain) current. The system can be designed with a built-in memory so that the system remembers if a signal has been applied.

Oscillator

The capacitance between the tube and the drain electrode is a function of time. Inserting a capacitance between the drain electrode and ground gives a time-dependent voltage, Vₒᵤₜ(t). With a feedback circuit 1420 connected between the drain and a gate voltage modulator 1410, this time-dependent voltage can be superimposed on the gate voltage bias, which gives a modulation voltage with a frequency corresponding to the vibration frequency of the tube.

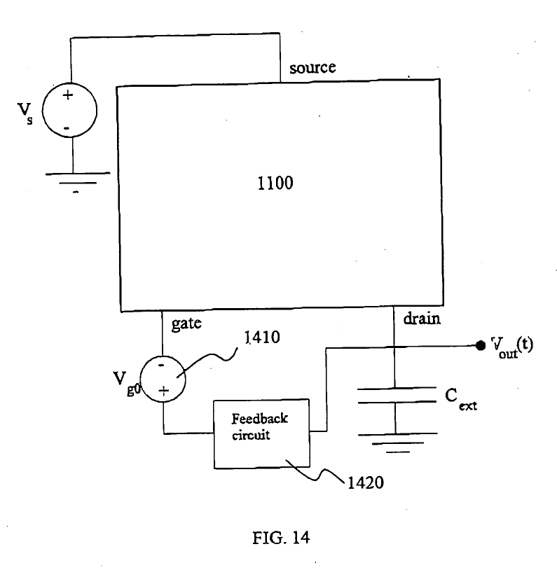

This structure is illustrated in FIG. 14. With the feedback the tube therefore starts to oscillate in resonance. The oscillation may be started by applying a step pulse to the gate electrode. The oscillation frequency is tunable by the gate bias. The nanoelectromechanical component in this example can be either in the contact or non-contact mode.

In other words, FIG. 14 shows how an output signal, which has a frequency determined by the resonance frequency, can be fed back via the feedback circuit 1420 to modulate the gate signal. With an appropriate phase shift this signal drives the oscillations.

Variable Capacitor

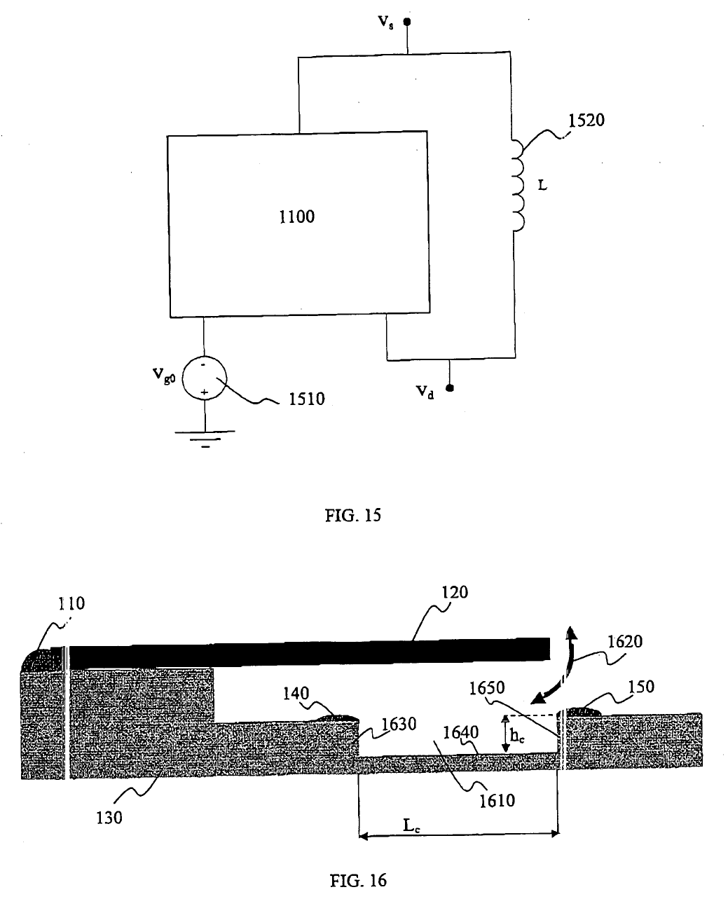

The capacitance between the tube and the drain is a function of gate voltage. Thus, the system can act as a tunable capacitor which in turn can be used in an electrical resonance circuit, see FIG. 15. An inductive component 1520 with inductance L is connected between the source and the drain. The mechanical oscillation of the tube can be minimized by using a small V_{sd}, or by actively damping tube oscillations using a feedback to the gate with an appropriate phase shift (not depicted in the figure).

In other words, FIG. 15 shows a variable capacitor, where the tube-drain capacitance depends on the gate voltage. The system is a variable capacitor that can be used to change the resonance frequency of an electric resonance circuit.

Pulse Generator

The contact mode system can be used as a pulse generator by applying an AC signal to the gate, with a suitable amplitude and frequency such that, during one cycle, the tube tip contacts the drain electrode for part of the cycle.

Electromechanical Mixer

By allowing higher mechanical modes of the tube motion, and by applying an AC signal with a suitable frequency to an appropriately placed gate electrode, the system will exhibit coupled mechanical motion, and may be used as a mechanical frequency mixer.

Additional Devices

Additional applications may be constructed by connecting a multitude of individual devices to each other.

Cavity

FIG. 16 shows another embodiment of a nanoelectromechanical component according to the present invention. The substrate 130 is provided with a cavity 1610 under the nanotube provided with defining surfaces 1630, 1640 and 1650. The cavity is preferably having a depth h_{c} and a length L_{c}, and a width (not shown) sufficient to house the tube 120, when the tube oscillates with large amplitude as indicated by arrow 1620, thereby enabling greater movement of said nanotube, without the tube 120 making contact with the substrate 130. In this embodiment the drain electrode 150 is arranged beyond the tube 120.

In the claims

1. A nanotube device, comprising a nanotube with a base end and a tip end and with a longitudinal and a lateral extension, a supporting structure for supporting at least a first part of the nanotube, and first means for exerting a force upon the nanotube in a first direction defined by its lateral extension, where at least a second part of the nanotube protrudes beyond the support of said structure, so that when said force exceeds a certain level, the second part of the nanotube will flex, and thereby reducing a tube-to-drain distance between the tube and a drain electrode, wherein a source electrode is arranged having a distance to the tube such that quantum mechanics phenomena can be made to occur between the tube and said source electrode.

2. A nanotube device according to claim 1, wherein the first means for exerting said force upon the nanotube is an electrical means, the force being created by applying a voltage to the means, and in that dimensions of said nanotube and a size of a vertical distance between the tube and the supporting structure, and a size of a horizontal distance between a tube and the drain electrode is such that quantum mechanics phenomena can be made to occur between the tube and said drain electrode.

3. A nanotube device according to claim 1, wherein said supporting structure comprises a terraced structure with structures on a first and a second level, with the supported first part of the nanotube being supported by the first level of the structure, and said means for exerting force being located on said second level.

4. A nanotube device according to claim 1, wherein the first means for applying force comprises a first gate electrode, and a first circuit which impedance is affected by the flexing of the nanotube comprises a first gate electrode being located on said second level of the structure and a first source electrode being located on said first level of the structure.

5. A nanotube device according to claim 1, wherein the supporting terraced structure additionally comprises a structure on a third level, said third level being located essentially in parallel with said second level, but on an opposite side of the protruding part of the nanotube, which nanotube device comprises second means for exerting a force upon the nanotube in a second direction defined by its lateral extension, so that when said force exceeds a certain level, the second part of the nanotube will flex in the second direction of its lateral extension, and thereby affect the impedance of a second electrical circuit.

6. A nanotube device according to claim 5, wherein the second means for exerting said force upon the nanotube is an electrical means, the force being created by applying a voltage to the means.

7. A nanotube device according to claim 5, wherein the additional supporting structure comprises a terraced structure with structures on a first and a second level, with the supported first part of the nanotube being supported by the first level of the structure, and said means for exerting force being located on said second level.

8. A nanotube device according to claim 5, wherein the second means for applying force comprises a second gate electrode, and the second circuit which impedance is affected by the flexing of the nanotube comprises a second drain electrode being located on said third level of the structure.

9. A nanotube device according to claim 1, wherein the device comprises two gate electrodes and two drain electrodes, where the gate electrodes are arranged, one on each side of the nanotube, and below, and where the drain electrodes are arranged, one on each side and below, relatively to the nanotube.

10. A nanotube device according to claim 1, wherein comprises one gate electrode and two drain electrodes; the gate electrode is arranged directly under the nanotube, whilst the two drain electrodes are arranged, one on each side of the nanotube, opposite of each other.

11. A nanotube device according to claim 1, wherein said device comprises two gate electrodes and one drain electrode, the gate electrodes are arranged, one on each side of the nanotube and opposite of each other.

12. A nanotube device according to claim 1, wherein said device comprises four gate electrodes, and two drain electrodes, the gate electrodes are arranged two on each side of the nanotube in a quadratic or rectangular fashion in pairs and the drain electrodes are arranged one on each side of the nanotube opposite of each other.

13. A nanotube device according to claim 1, wherein said device comprises two gate electrodes and two drain electrodes where the gate electrodes are arranged one on each side of the nanotube and below and closer to the tip of the tube than the gate electrodes and where the drain electrodes are arranged beyond the nanotube, one on each side of the imaginary extension of said tube.

14. A nanotube device according to claim 1, wherein said device comprises two gate electrodes and two drain electrodes where the gate electrodes are arranged asymmetrically with reference to the nanotube.

15. A memory element, wherein it comprises the device of claim 1.

16. A filter, wherein it comprises the device of claim 1, where an input AC signal is applied to the gate of the device and the output signal is read at the drain.

17. The filter of claim 16, wherein it is possible to tune a resonance frequency by means of a gate voltage bias.

18. A variable bandwidth detector, wherein it comprises the device of claim 1, where the gate of the device is connected to a gate voltage modulator.

19. An oscillator, wherein it comprises the device of claim 1.

20. The oscillator of claim 19, wherein a feedback circuit is connected between the drain and a gate voltage modulator.

21. A variable capacitor, wherein it comprises the device of claim 1.

22. The capacitor of claim 21, wherein an inductive component is connected between the source and the drain.

23. A device according to claim 1, where said tube is made of carbon, silicon carbide or metal and/or is a nanowire or a nanowhisker.

24. A nanotube device according to claim 1, wherein said device is provided with a cavity in the substrate under the nanotube enabling greater movement of said nanotube.
